(19) United States
(12) Patent Application Publication
(10) Pub. No.: US 2016/0377684 A1
(43) Pub. Date: Dec. 29, 2016

(54) ASSESSING THE QUANTITY OF ENERGY IN A MOTOR VEHICLE BATTERY

(71) Applicant: RENAULT S.A.S., Boulogne-Billancourt (FR)

(72) Inventors: Sylvain LEIRENS, Grenoble (FR); Sylvain LALLICH, Lans-en-Vercors (FR)

(73) Assignee: RENAULT s.a.s., Boulogne-Billancourt (FR)

(21) Appl. No.: 15/102,382

(22) PCT Filed: Dec. 2, 2014
(86) PCT No.: PCT/FR14/53121

§ 371 Date: Sep. 13, 2016

(30) Foreign Application Priority Data
Dec. 12, 2013 (FR) 1362491

(51) Int. Cl. G01R 31/36; B60L 11/18; G01R 31/00

(52) U.S. Cl. CPC G01R 31/3651; G01R 31/007; G01R 31/3662; G01R 31/3675; B60L 11/1861

(57) ABSTRACT

A method for evaluating a quantity of energy at constant power of a battery includes determining a value of a capacity parameter for the battery, constructing a table of values for a parameter of voltage across terminals of the battery as a function of a value of a current parameter, for N values of a state of charge parameter, determining a value of an internal resistance parameter for the battery, providing a table of values of an open-circuit voltage parameter, estimating a value of the state of charge parameter at an initial time, and estimating a quantity of energy parameter between a final and initial states of charge using a function whose variable is the state of charge parameter and whose parameters are said value of the capacity parameter for the battery, said value of the internal resistance parameter, and said value of the open-circuit voltage parameter.

The invention relates to the control of an automobile vehicle battery. The invention relates in particular to the evaluation of the available or extractible energy in a battery of an automobile vehicle, notably an electric or hybrid vehicle. The invention also relates to the evaluation of the quantity of energy to be accumulated during a charge phase of the battery.

For a given state of charge or SOC, the energy extractible from a battery is a function of the temperature. Indeed, the lower the temperature of the battery, the higher the internal resistances of the battery. For the same level of current, the average voltage may become lower for the whole of the discharge.

It is known for automobiles vehicles to be equipped for example with battery management systems, or BMS, allowing, amongst other things, the available energy to be evaluated. The calculation of this available energy requires the knowledge of the capacity (in Ah) of the battery, its internal resistance and the open-circuit voltage (OCV) of the battery as a function of the state of charge. However, the capacity and the internal resistance of the battery are characteristics that vary over the lifetime of the battery. The precision of determination of the quantity of available energy is thus linked to the knowledge of these values, which are however generally approximated by mappings necessitating a large quantity of tests for their generation.

The document US 2006/202663 A1 describes a method for estimating the residual capacity of a battery, in which an initial value of the SOC is determined by taking into account the variation of the open-circuit voltage as a function of the temperature and of the aging of the battery. For this purpose, a mapping of the SOC as a function of the temperature and of the open-circuit voltage is established and recorded in the BMS, and then a measurement of the temperature and of the open-circuit voltage allows an initial value of the SOC to be determined. This method does not however allow the variation over time of either the internal resistance or of the capacity of the battery to be taken into account. Furthermore, the measured value of the OCV used for the determination of the initial value of an SOC may be erroneous if the battery is not in a sufficiently relaxed state, resulting in an incorrect estimate of the initial value of the SOC.

There therefore exists a need for a more precise evaluation of the quantity of energy of a battery, notably allowing at least a part of the parameters to be updated in the course of the aging of the battery.

A method is provided for evaluating a quantity of energy at constant power of a battery of an automobile vehicle, said quantity of energy corresponding to an extractible quantity of energy or to a quantity of energy to be accumulated, said method comprising:
(a) determine a value of a capacity parameter Q for the battery,
(b) construct, notably during a charge phase of the battery, a table of values for a parameter of voltage across the terminals of the battery as a function of the value of a current parameter for N values of a state of charge parameter (z),
(c) determine a value of an internal resistance parameter R(z) for the battery as a function of said state of charge parameter (z) for said battery based on the table constructed at the step (b),
(d) provide a table of values of an open-circuit voltage parameter Uoc(z) for the battery as a function of the state of charge parameter (z) for the battery,
(e) estimate a value of the state of charge parameter (z₀) for the battery at an initial time t₀, corresponding to an initial state of charge of the battery,
(f) estimate by calculation a value of a quantity of energy parameter Eₚ between a final state of charge and said initial state of charge using a function f(z) whose variable is the state of charge parameter (z) and whose parameters are said value of the capacity parameter Q for the battery, said value of the internal resistance parameter R(z) and said value of the open-circuit voltage Uoc(z).

It could be provided to transmit to a user interface a signal generated as a function of the quantity of energy thus estimated.

The steps for determining the values of capacity Q and internal resistance R(z) parameters allow a regular update of these values in the course of the aging of the battery and, consequently, allow this aging to be taken into account in the calculation of the estimate of the quantity of energy, which can allow the precision of these values, and consequently the precision of the calculation of the estimate of the quantity of energy, to be improved.

The step (a) can thus be regularly iterated over the lifetime of the battery, notably independently of the implementation of the other steps. In other words, the value of a capacity parameter determined at the step (a) may be used for several iterations of the other steps. The iteration of the step (a) may be carried out at predetermined intervals of time or when certain conditions of use are met, for example during a total charge phase of the battery, after a predetermined number of charge/discharge cycles, after a certain mileage travelled or other.

The value of the capacity parameter Q determined at the step (a) may be determined by metering the quantity of current flowing through the battery during a charge phase of the latter. Advantageously, this determination may be carried out during a total charge phase of the battery, but a determination during a partial charge phase is also possible.

The capacity parameter Q may be a capacity value, a parameter having a value proportional to the value of the capacity or other.

The step (b) for construction of a table may also be regularly repeated over the lifetime of the battery, notably independently of the implementation of the other steps, in particular independently of the iteration of the step (a) and of the steps (e) and (f).

The state of charge parameter (z) may be the SOC, a parameter allowing the SOC to be determined, or other.

The N values of the state of charge parameter may be spread in steps between a minimum value of a state of charge corresponding to a minimum state of charge achievable (battery completely empty) and a maximum value of a state of charge corresponding to a maximum state of charge achievable (battery completely charged). By way of example, the number N may be less than or equal to 25, preferably less than 20, for example equal to 10, and preferably greater than or equal to 9.

The parameter representative of a current may for example be a value of a current, a parameter having a value proportional to the value of the current, or other. The parameter representative of the voltage across the terminals of the battery may for example be a voltage value, a parameter having a value proportional to the value of the voltage, or other. The invention is not in any way limited to the exact nature of these parameters.

This construction step (b) may be carried out during a charge phase of the battery, for example by measuring the value of the voltage parameter and the value of the current parameter (charging current) for various states of charge of the battery.

By providing the determination of the value of an internal resistance parameter R(z) for the battery as a function of the state of charge (z) based on a constructed table of values and not on a mapping, the method according to the invention can enable a more precise determination of this internal resistance in the course of the aging of the battery.

During the step (d), the table of the values Uoc(z) as a function of the state of charge parameter (z) for the battery may be obtained from the table constructed at the step (b), the value of the open-circuit voltage parameter being able to be determined when the value of the current parameter is zero and the battery relaxed. Notably, Uoc(z) may be approximated by a polynomial of order less than or equal to N-1 using the N values in the table, an approximation for example with a polynomial based on a least squares fit. Other approximations may however be envisioned, such as interpolation, linear or otherwise, preferably linear. Furthermore, this table could also be a table established in a prior step, notably by experimental measurements, and recorded, for example in the form of a mapping.

The initial state of charge is a state of charge at an initial time to corresponding to a mission start time, for example when the vehicle is started, or to a time when the vehicle is being driven.

Advantageously and in a non-limiting manner, the step (e) for estimating the value of the initial state of charge parameter (z₀) may comprise, at the initial time t₀:

(i) measuring the value of the parameter of voltage across the terminals of the battery and the value of the parameter of current flowing in the battery when said value of the current parameter is stable for a predetermined period of time during a discharge phase of the battery,

(ii) deducing from this the value of the initial state of charge parameter (z₀) based on the table constructed at the step (b).

Said value of the current parameter is said to be stable when it does not vary over a predetermined period or when it varies very little. By way of example, it may be considered that the value of the current parameter varies very little when it does not vary by more than 10% to 20%, for example no more than 15%, with respect to its average value over the predetermined period, for example of 10 s. It goes without saying that the invention is not limited by the predetermined period, nor by the percentage of variation.

The invention is not however limited by this method of determination of the state of charge parameter based on the table constructed at the step (b) and other methods could be used.

Advantageously and in a non-limiting manner, the step (e) may comprise the following additional steps:

(iii) estimate a second value of the initial state of charge parameter (z′₀) by another prediction method,

(iv) compare the first value of the initial state of charge parameter (z₀) determined at the step (ii) with the second value of the initial state of charge parameter (z′₀) determined at the step (iii),

(v) use the value of the initial state of charge parameter (z₀) determined at the step (ii) if the difference z₀-z′₀ is less than a predetermined value, otherwise, use the second value of the initial state of charge parameter (z′₀) determined at the step (iii).

This sequence may allow the determination of the value of the initial state of charge parameter to be improved by comparing the values estimated by means of two different methods.

Notably, the step (iii) may use a method of prediction based on coulomb metering.

The step (f) for estimating by calculation a value of a quantity of energy parameter Eₚ between a final state of charge and said initial state of charge is implemented using a function f(z) whose variable is the state of charge parameter (z). This formulation allows the calculations to be simplified, the quantity of energy then being estimated between an initial value of state of charge parameter and a final value of state of charge parameter. This estimation step (f) is implemented for a predetermined value of power parameter. This value of power parameter may be a power value, a parameter proportional to the power value or other. The predetermined value of power parameter may correspond to a value provided for use of the battery.

The quantity of energy parameter Eₚ may be a value of a quantity of energy, a parameter proportional to the value of a quantity of energy or other.

The final state of charge is a state of charge at a final time t_{f} corresponding to a time later than the initial time.

The final state of charge may notably be defined as the state of charge reached for a predetermined threshold value of a parameter of voltage U_{final} across the terminals of the battery.

Notably, the final state of charge parameter (z)) may thus be obtained by solving the following equation:

$${U}_{final} = Uoc ( {z}_{f} ) + R ( {z}_{f} ) \frac{P}{{U}_{final}} \qquad ( 1 )$$

where Uoc(z_{f}) is the value of the open-circuit voltage parameter of the battery at the final state of charge, R(z_{f}) is the internal resistance of the battery at the final state of charge and P is the value of the power parameter in question.

Uoc(z) may be determined from the table in the step (d) of the method, notably by the methods described hereinabove.

R(z_{f}) may be determined from the table in the step (c) of the method.

When the method is used for determining a quantity of energy extractible from the battery, notably during a discharge phase of the battery, the threshold value of the voltage parameter U_{final} may be defined as a minimum value authorized for the battery.

When the method is used for determining a quantity of energy remaining to be accumulated in the battery, notably during a charge phase of the battery, the threshold value of the voltage parameter U_{final} may be defined as a maximum value to be reached or reachable.

Advantageously and in a non-limiting manner, the function f(z) used in the step (f) for estimating the quantity of energy may be written:

f(z)=Uoc(z)+{square root over (Δ)z))} (2),

in which:
Δ(z) is a term taking into account the energy losses, being a function of the value of the state of charge parameter (z),
Uoc(z) represents the open-circuit voltage parameter as a function of the value of the state of charge parameter (z). The value of the quantity of energy parameter is then obtained by integration of this function f(z) between the value of the state of charge parameter in the initial state (z₀) and the value of the state of charge parameter in the final state (z_{f}), said value of the final state of charge parameter (z_{f}) being the solution of the above-mentioned equation (1).

In particular, the function f(z) may be approximated by a polynomial of order n less than or equal to N-1. The value of quantity of energy parameter Eₚ may then be expressed by:

$${E}_{P} \approx \frac{Q}{2} ( r ( {z}_{f} ) - r ( {z}_{0} ) ) . \qquad ( 3 )$$

where r(z) is the integral of said polynomial of order n, and Q represents the capacity parameter.

Advantageously and in a non-limiting manner, after the step (f), the method may comprise the following step:
(g) determine a new value of the initial state of charge parameter (z″₀) using the value of quantity of energy parameter Eₚ estimated at the step (f).

The new value of the initial state of charge parameter (z″₀) determined during the above-mentioned step (g) may be used for implementing the step (f) for another value of power parameter P. In other words, the steps (e) to (f) may be implemented for a first value of power parameter P₁, then the step (f) may be implemented for a second value of power parameter P₂ (different from P₁) using the value of the initial state of charge parameter (z″₀) determined at the step (g).

As already mentioned, the value of the power parameter P used for the calculation of the steps (e) and (f) may belong to a set of usable predetermined values, corresponding for example to discharge powers representative of usages of the vehicle or to charge powers. It may thus be useful to estimate the quantity of energy Eₚ for various values of power parameter P. These estimations may be obtained by iterating the steps (e) and (f) for various values of power parameter P.

A device is furthermore provided for evaluating a quantity of energy of a battery of an automobile vehicle at constant power, said quantity of energy corresponding to an extractible quantity of energy or to a quantity of energy to be accumulated. This device comprises:

receiving means designed to receive various values of parameters including a value of a parameter of voltage across the terminals of the battery, a value of a current parameter, and potentially a value of a time parameter,

means arranged for storing the values received by the receiving means and storing a table of values of a parameter of voltage across the terminals of the battery as a function of the value of a current parameter, for N values of a state of charge parameter (z) of said battery and a table of values of an open-circuit voltage parameter Uoc(z) for the battery as a function of the state of charge parameter (z) for the battery,

processing means arranged for
determining a value of a capacity parameter Q for the battery,
constructing a table of values of a parameter of voltage across the terminals of the battery as a function of the value of a current parameter for N values of a state of charge parameter (z) for said battery,
determining a value of an internal resistance parameter R(z) for the battery as a function of said state of charge parameter (z) for said battery using the table constructed,
estimating a value of the state of charge parameter (z₀) for the battery at an initial time to, corresponding to an initial state of charge of the battery, notably as a function of the table stored in the storage means, and
estimating by calculation a value of quantity of energy parameter Eₚ between a final state of charge and said initial state of charge using a function f(z) whose variable is the state of charge parameter (z) and whose parameters are said value of the capacity parameter Q of the battery, said value of the internal resistance parameter R(z) and said value of the open-circuit voltage Uoc(z).

The device may furthermore comprise transmission means arranged for transmitting to a user interface a signal generated as a function of the value of quantity of energy thus estimated.

A battery management system for an automobile vehicle is furthermore provided, for example a BMS or other, incorporating such a device.

This system and/or this device may comprise or be integrated into one or more processors, for example microcontrollers, microprocessors or other types.

The receiving means may comprise an input pin, an input port or other. The storage means may comprise a RAM (for Random Access Memory), an EEPROM (for Electrically-Erasable Programmable Read-Only Memory), a ROM (for Read-Only Memory) or other. The processing means may for example comprise a processor core or CPU (for Central Processing Unit). The transmission means may for example comprise an output port, an output pin or other.

An automobile vehicle is furthermore provided comprising a battery management system such as described hereinabove, and potentially comprising a battery. This vehicle may for example be an electric and/or hybrid vehicle.

A computer program product is furthermore provided comprising the instructions for carrying out the steps of the method described hereinabove when these instructions are executed by a processor.

The invention will be better understood with reference to the figures, which illustrate non-limiting embodiments.

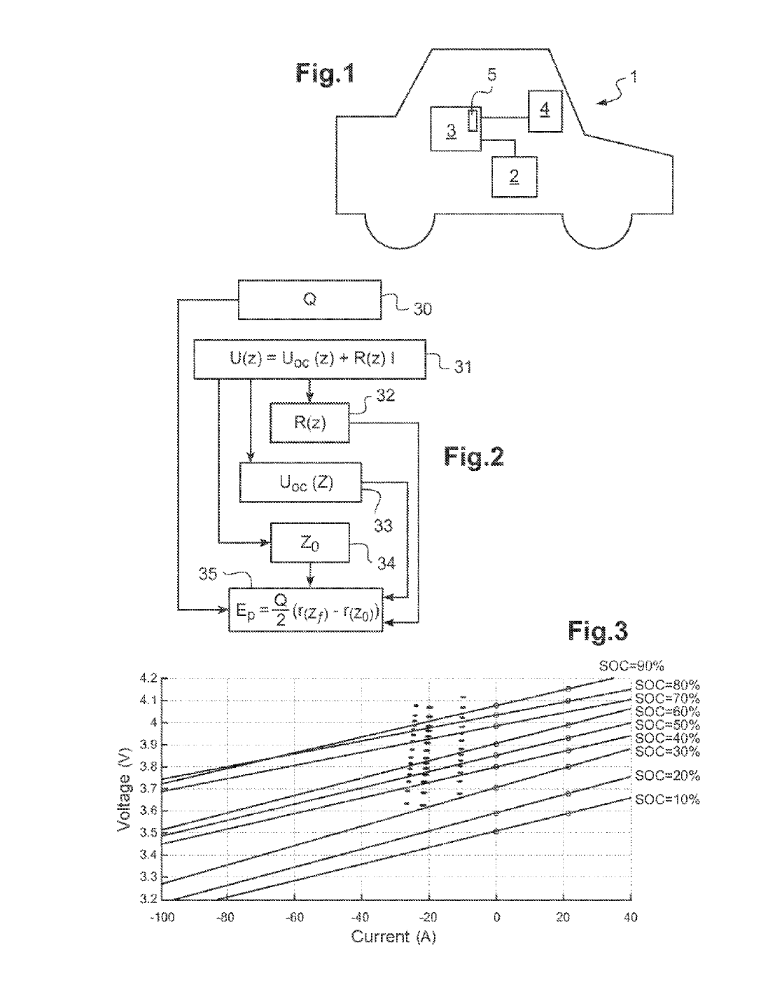

FIG. 1 shows one example of a vehicle according to one embodiment of the invention.

FIG. 2 is a timing diagram of one example of a method according to one embodiment of the invention.

FIG. 3 shows a set of curves showing the variation of the voltage across the terminals of the battery as a function of the current for several states of charge SOC of the battery.

With reference to FIG. 1, an automobile vehicle 1, for example an electric vehicle, may comprise a power battery 2 designed to drive this vehicle, a system for managing the battery 3, called BMS, and a user interface 4, for example a dashboard.

The BMS 3 allows the charge and the discharge of the battery 2 to be controlled, and allows the display of messages on a screen (not shown) of the user interface 4 to be controlled.

The BMS 3 incorporates a device 5 for evaluation of the available energy or of the energy to be accumulated in the battery 2, for example a part of a processor. This device 5 may notably be activated when the user turns the key in order to start the vehicle, and also in the course of a mission, or else during charge phases of the battery.

The BMS 3 is in communication with voltage and current measurement devices, for example a cell voltage measurement ASIC (ASIC: acronym for Application-Specific Integrated Circuit) and an ammeter (not shown).

With reference to FIG. 2, a method according to one embodiment of the invention may comprise a step 30 consisting in determining the capacity Q of the battery.

This capacity Q may for example come from a coulomb metering carried out during a partial or total charge of the battery by means of a current sensor across the terminals of the battery, or else of several sensors across the terminals of the cells of the battery, and of a clock. The capacity may notably be calculated by the BMS based on the values measured by the sensors as a function of the charging time and potentially based on an initial state of charge of the battery, if this calculation is carried out during a partial charge of the battery.

This step 30 may be carried out regularly but not necessarily at each start-up of the vehicle, the variation of the capacity of the battery as a function of time being relatively slow, or during particular states of the battery or of the vehicle. A periodicity of several days or weeks may thus be envisioned. During a step 31, notably during a charge phase, the variation of the voltage as a function of the current for N states of charge z is recorded in a memory, these N states of charge varying for example from 0 to 100%. These measurements may be recorded in the form of tables or of a set of curves of the type shown in FIG. 3, for each of the N states of charge. FIG. 3 shows the variation of the voltage U (in V) as a function of the current I (in A) across the terminals of a cell forming part of a battery pack. In FIG. 3, only the curves corresponding to the states of charge z=SOC going from 10 to 90% are shown.

These tables or curves are constructed by the BMS using the values measured by current and voltage sensors during the charge phase. They may be constructed regularly, for example at each charge of the battery or at each total charge of the battery or at predetermined intervals of time.

During a step 32, the internal resistance R(z) of the battery is determined as a function of the state of charge (z) of the battery using the table previously constructed at the step 31 and recorded.

Indeed, the relationship between the voltage U(z) across the terminals of the battery and the current I flowing through the battery may notably be expressed by the equation:

U(z)=Uoc(z)+R(z)I (4),

in which:

U(z) represents the voltage across the terminals of the battery as a function of the state of charge z, in Volts,

Uoc(z) represents the open-circuit voltage of the battery as a function of the state of charge z, in Volts,

I represents the current flowing through the battery, in A,

R(z) represents the internal resistance of the battery as a function of the state of charge z, in Ω,

By considering that the internal resistance R(z) of the battery does not vary in charge (I>0) or discharge (I<0) and by considering that the value of the open-circuit voltage Uoc is invariant with the temperature and the aging of the battery, it is thus possible to determine the internal resistance R(z) of the battery for each of the N values of state of charge z using the table constructed at the step 31.

These N values of internal resistance may be determined by the BMS and stored in the memory.

This determination of the internal resistance R(z) of the battery as a function of the state of charge may be carried out at each update of the table constructed at the table 31, for example at each charge of the battery.

During a step 33, a table is generated of the open-circuit voltage Uoc(z) of the battery as a function of the state of charge (z) of the battery. This table is generated based on experimental measurements performed prior to use of the battery in the vehicle. Using the N values of the table constructed at the step 33, it is possible to approximate Uoc(z) either by a polynomial of order less than or equal to N-1 based on a least squares fit, or by an interpolation, preferably linear.

It could however also be envisaged to generate this table Uoc(z) using the table constructed at the step 31 by reading the value of the voltage when the current is zero for each state of charge. In this case, it is preferable to generate the table Uoc(z) when the step 31 is implemented at the start up of the vehicle after a long stop, in order to obtain measurements of the open-circuit voltage while the battery is completely relaxed.

During a step 34, an initial state of charge z₀ of the battery is estimated at an initial time to.

For this purpose, in the course of a discharge phase of the battery, in other words during driving, a pair of values of the voltage and of the current (U, I) may for example be measured and recorded, for which the current I (discharge current) is stable for a predetermined period, for example of 10 s. For example, this current I is stable when it does not vary by more than 15% with respect to its average value calculated over this period of 10 s. This point (U, I) can be copied into the table or plotted on the curves constructed during the step 31, which allows the value z₀ to be deduced. This correlation can be carried out by the BMS. In FIG. 3, several of these pairs (U, I) are plotted for values of discharge current of 10 A and 20 A.

Optionally, the initial state of charge z₀ thus estimated could be compared with an initial state of charge z′₀ obtained by another method of determination based on coulomb metering. It is then possible to re-adjust this initial value of state of charge to the value z′₀ if z₀ differs from z′₀ by a predetermined value. Tests have shown that the estimated value of a state of charge z₀ only differs from the value of the state of charge, measured by coulomb metering, by around 1% to 5%.

During a step 35, a quantity of energy Eₚ between a fmal state of charge z_{f} and the initial state of charge z₀ previously estimated is estimated by calculation. For this purpose, a function f(z) is used whose variable is the state of charge parameter z and whose parameters are the capacity Q determined at the step 30, the internal resistance R(z) determined from the step 32 and the open-circuit voltage Uoc(z) determined from the step 33.

This function f(z) may then be written in the following manner:

f(z)=Uoc(z)+\sqrt{Δ(z)} (2),

in which:

Δ(z) is a term taking into account the energy losses, being a function of the state of charge z, in V²,

The quantity of energy Eₚ is then obtained by integration of this function f(z) between the value of the state of charge parameter in the initial state (z₀) and the value of the state of charge parameter in the final state (z_{f}) defined as being the solution of the equation (1):

$${U}_{final} = Uoc ( {z}_{f} ) + R ( {z}_{f} ) \frac{P}{{U}_{final}} \qquad ( 1 )$$

in which:

Uoc(z_{f}) is the value of the open-circuit voltage parameter for the battery in the final state of charge,

R(z_{f}) is the internal resistance of the battery in the final state of charge

P is the value of the power parameter (constant).

The quantity of energy Eₚ may then be written:

$${E}_{P} = \frac{Q}{2} {{\int }_{{z}_{0}}}^{{z}_{f}} f ( z ) d z , \qquad ( 5 )$$

in which

Eₚ represents the quantity of energy, in W.h

Q represents the capacity of the battery in A.h.

Notably, since the power P is constant, this power is given by the following equation:

P=U(t)I(t)=Uoc(z(t))I(t)+R(z(t))I(t)² (6)

in which:

U(t) represents the voltage across the terminals of the battery as a function of time, in V,

I(t) represents the current flowing through the battery as a function of time, in A,

z(t) represents the state of charge as a function of time, in %,

Uoc(z(t)) represents the open-circuit voltage of the battery as function of the state of charge, in V,

R(z(t)) represents the internal resistance of the battery as a function of the state of charge, in Ω.

This equation (6), of the 2^{nd} degree in I, is parameterized by the state of charge z. Therefore, for a given z, I(z) may be calculated by solving this equation (5) whose discriminant is the term Δ(z) from the equation (2) and is written:

Δ(z)=Uoc²(z)+4R(z)P (7)

In one advantageous embodiment, in order to simplify the integration of the function f(z) and the calculation of the quantity of energy, this function f(z) may be approximated by a polynomial of order n less than or equal to N-1. The quantity of energy is then expressed by:

$${E}_{P} \approx \frac{Q}{2} ( r ( {z}_{f} ) - r ( {z}_{0} ) ) . \qquad ( 3 )$$

where r(z) is the primitive of said polynomial of order n.

More precisely, the idea is to approximate f(z) by a polynomial q(z) based on a least squares fit. Notably, if there are N values of Uoc and of R as a function of z (for example according to the steps 32 and 33), this polynomial q(z) is then of order less than or equal to N-1 and may be written:

q(z)=aₙzⁿ+aₙ₋₁zⁿ⁻¹+ . . . a₁z+a₀ (8)

in which aₙ, aₙ₋₁, . . . a₀ are coefficients.

Then

$$r ( z ) = \int q ( z ) d z = \frac{{a}_{n}}{n + 1} {z}^{n + 1} + \frac{{a}_{n - 1}}{n} {z}^{n} + … + \frac{{a}_{1}}{2} {z}^{2} + {a}_{0} z + k \qquad ( 9 )$$

where k is the constant of integration.

It will be noted that, since the power P is constant, it is then possible to determine the final time t_{f} when the final state of charge z_{f} is reached by the equation:

$$( {t}_{f} - {t}_{0} ) = \frac{{E}_{P}}{P} . \qquad ( 10 )$$

The knowledge of this final time t_{f} may allow it to be known whether, in discharge mode, sufficient energy will be available to guarantee a power P for a certain period of time (e.g.: P for 10 s, the time for overtaking a vehicle) or to determine a duration of charge at constant power P, and irrespective of the initial state of charge.

It will be noted that the knowledge of the quantity of energy Eₚ allows the initial state of charge z″₀ to be recovered (in other words to recalculate it) by solving the equation (3) in z₀:

$${E}_{P} - \frac{Q}{2} ( r ( {z}_{f} ) - r ( {z}_{0} ) ) = 0 ,$$

the final state of charge (zⱼ) being calculated as previously by solving (1).

This recalculated initial state of charge z″₀ may be used to determine a new quantity of energy E_{P2} corresponding to a constant power P₂ different from the power previously used to determine Eₚ.

It will lastly be noted that the steps 30, 31 and 33 of the method may be iterated independently of one another and independently of the iteration of the steps 34 and 35. According to variants, the steps 32 and 33 could be implemented at each iteration of the step 31.

The iteration of the step 30 and of the step 32 allows the variation in the capacity of the battery and in its internal resistance to be taken into account during the aging of the battery, which can allow a better estimation of the quantity of energy.

The method described in the present invention furthermore offers the advantage of being able to be applied both to the management of the charging of the battery and to the management of its discharge and notably allows the charging time remaining during a charging process at constant power to be estimated.

1-10. (canceled)

11. A method for evaluating a quantity of energy at constant power of a battery of an automobile vehicle, said quantity of energy corresponding to a extractible quantity of energy or to a quantity of energy to be accumulated, said method comprising:
(a) determining a value of a capacity parameter for the battery;
(b) constructing, during a charge phase of the battery, a table of values for a parameter of voltage across terminals of the battery as a function of a value of a current parameter for N values of a state of charge parameter;
(c) determining a value of an internal resistance parameter for the battery as a function of a state of charge parameter for said battery based on the table constructed at the step (b);
(d) providing a table of values of an open-circuit voltage parameter for the battery as a function of the state of charge parameter for the battery;
(e) estimating a value of the state of charge parameter for the battery at an initial time, corresponding to an initial state of charge of the battery; and
(f) estimating by calculation a value of a quantity of energy parameter between a final state of charge and said initial state of charge using a function whose variable is the state of charge parameter and whose parameters are said value of the capacity parameter for the battery, said value of the internal resistance parameter and said value of the open-circuit voltage parameter.

12. The method as claimed in claim 11, in which the function used in the step (f) for estimating the quantity of energy is written:
f(z)=Uoc(z)+\sqrt{Δ(z)} (2),
in which:
Δ(z) is a term taking into account the energy losses, being a function of the value of the state of charge parameter,
Uoc(z) represents the open-circuit voltage parameter as a function of the value of the state of charge parameter,
and the value of the quantity of energy parameter is obtained by integration of said function between the value of the state of charge parameter in the initial state and the value of the state of charge parameter in the final state, said value of the final state of charge parameter being the solution of the equation:
$${U}_{final} = Uoc ( {z}_{f} ) + R ( {z}_{f} ) \frac{P}{{U}_{final}} \qquad ( 1 )$$
in which:
U_{final} represents the parameter of voltage across the terminals of the battery in the final state of charge,
R(z_{f}) represents the internal resistance parameter of the battery in the final state of charge,
Uoc(z_{f}) represents the open-circuit voltage parameter as a function of the value of the final state of charge parameter, and
P is the constant value of the power parameter.

13. The method as claimed in claim 12, in which the function is approximated by a polynomial of order n less than or equal to N-1 and said value of quantity of energy parameter is expressed by:
$${E}_{P} \approx \frac{Q}{2} ( r ( {z}_{f} ) - r ( {z}_{0} ) ) . \qquad ( 3 )$$
in which:
r(z) is the integral of said polynomial of order n, and
Q represents the capacity parameter.

14. The method as claimed in claim 11, in which the steps (a) and (b) are iterated over a lifetime of the battery, independently of each other and of the steps (e) and (f) of said method.

15. The method as claimed in claim H, in which the step (e) for estimating the value of the initial state of charge parameter comprises, at the initial time:
(i) measuring the value of the parameter of voltage across the terminals of the battery and the value of the parameter of current flowing in the battery when said value of the current parameter is stable for a predetermined period of time during a discharge phase of the battery, and
(ii) deducing from the measuring the value of the initial state of charge parameter based on the table constructed at the step (b).

16. The method as claimed in claim 15, in which the step e comprises the following additional steps:
(iii) estimating a second value of the initial state of charge parameter by another prediction method,
(iv) comparing the first value of the initial state of charge parameter determined at the step (ii) with the second value of the initial state of charge parameter determined at the step (iii), and
(v) using the value of the initial state of charge parameter determined at the step (ii) if the difference from the comparing is less than a predetermined value, otherwise, using the second value of the initial state of charge parameter determined at the step (iii).

17. The method as claimed in claim 11, further comprising, after the step (f), the following additional step:
(g) determining a new value of the initial state of charge parameter using the value of quantity of energy parameter estimated at the step (f).

18. The method as claimed in claim 17, in which the steps (e) to (g) may be implemented for a first value of power parameter, then the step (f) may be implemented for a second value of power parameter using the value of the initial state of charge parameter determined at the step (g).

19. A device for evaluating a quantity of energy of a battery of an automobile vehicle at constant power, said quantity of energy corresponding to an extractible quantity of energy or to a quantity of energy to be accumulated, comprising:
receiving means to receive various values of parameters including a value of a parameter of voltage across terminals of the battery, a value of a current parameter, and potentially a value of a time parameter;
means for storing the values received by the receiving means and storing a table of values of a parameter of voltage across the terminals of the battery as a function of the value of a current parameter for N values of a state of charge parameter of said battery and a table of values of an open-circuit voltage parameter for the battery as a function of the state of charge parameter for the battery; and
processing means for:
determining a value of a capacity parameter for the battery,
constructing a table of values of a parameter of voltage across the terminals of the battery as a function of the value of a current parameter for N values of a state of charge parameter for said battery,
determining a value of an internal resistance parameter for the battery as a function of said state of charge parameter for said battery using the table constructed,
estimating a value of the state of charge parameter for the battery at an initial time, corresponding to an initial state of charge of the battery, as a function of the table stored in the storage means, and
estimating by calculation a value of quantity of energy parameter between a final state of charge and said initial state of charge using a function whose variable is the state of charge parameter and whose parameters are said value of the capacity parameter for the battery, said value of the internal resistance parameter and said value of the open-circuit voltage.

20. An automobile vehicle comprising:
a battery; and
the device as claimed in claim 19 for evaluating a quantity of energy for said battery at constant power.
